(19) United States
(12) Patent Application Publication
(10) Pub. No.: US 2025/0176196 A1
(43) Pub. Date: May 29, 2025

(54) SEMICONDUCTOR DEVICE

(71) Applicant: Mitsubishi Electric Corporation, Tokyo (JP)

(72) Inventors: Takuichiro SHITOMI, Tokyo (JP); Manabu YOSHINO, Tokyo (JP); Yasuo YAMAGUCHI, Tokyo (JP); Toshihiro IMASAKA, Tokyo (JP); Atsushi ITO, Tokyo (JP)

(73) Assignee: Mitsubishi Electric Corporation, Tokyo (JP)

(21) Appl. No.: 18/826,052

(22) Filed: Sep. 5, 2024

(30) Foreign Application Priority Data
Nov. 29, 2023 (JP) 2023-201752

(51) Int. Cl. H10D 1/20

(52) U.S. Cl. CPC H10D 1/20

(57) ABSTRACT

The semiconductor device includes a signal transmission element provided on an element structure in a high-withstand-voltage isolation region. The signal transmission element includes a primary coil that is provided on a side of a low potential region of the high-withstand-voltage isolation region and connected to the low potential region, and a secondary coil that is provided on a side of a high potential region of the high-withstand-voltage isolation region and connected to the high potential region. The primary coil and the secondary coil are magnetically coupled to each other by a magnetic field in a direction parallel to a main surface of a P type substrate.

### BACKGROUND OF THE INVENTION

### Field of the Invention

The present disclosure relates to a semiconductor device.

### Description of the Background Art

Japanese Patent No. 6843799 discloses a configuration that implements a signal transmission function with insulation and level shift by a magnetic coupling element instead of a transistor driven by a high voltage in a configuration of a high voltage IC (HVIC).

In a conventional technique, an insulating signal transmission element (the magnetic coupling element in Japanese Patent No. 6843799) is integrated on one chip of the HVIC. However, because the signal transmission element has a large size and becomes an invalid region, there is a problem that the chip size increases. In addition, in order to increase a withstand voltage, it is necessary to increase a thickness of an inter-wiring interlayer film, and there is a problem that a process cost increases.

### SUMMARY

The present disclosure has been made to solve the above problems, and an object of the present disclosure is to prevent the increase in the chip size and the increase in process cost in the semiconductor device having the insulating signal transmission element.

A semiconductor device of the present disclosure includes a semiconductor substrate and an element structure formed on the semiconductor substrate. The semiconductor device is divided into a low potential region, a high potential region, and a high-withstand-voltage isolation region in plan view. In the low potential region, a ground is set as a reference potential. The high potential region has a floating potential as a reference potential. The high-withstand-voltage isolation region is provided between the low potential region and the high potential region to separate the low potential region and the high potential region from each other. The semiconductor device includes the signal transmission element provided on an element structure in the high-withstand-voltage isolation region. The signal transmission element includes a primary-side element and a secondary-side element. The primary-side element is provided on a low potential region side of the high-withstand-voltage isolation region, and connected to the low potential region. The secondary-side element is provided on a high potential region side of the high-withstand-voltage isolation region, and connected to the high potential region. The primary-side element and the secondary-side element are magnetically coupled or capacitively coupled to each other by a magnetic field or an electric field in a direction parallel to a main surface of the semiconductor substrate.

The semiconductor device of the present disclosure includes the signal transmission element in the high-withstand-voltage isolation region that is an ineffective region, so that an additional ineffective region does not increase due to the provision of the signal transmission element, and an increase in a chip size can be prevented. In addition, because the potential difference between the signal transmission element and the element structure in a vertical direction is small, the thickness of an inter-wiring interlayer film can be reduced, and a process cost is reduced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view illustrating a semiconductor device according to a first preferred embodiment;

FIG. 2 is a sectional view illustrating the semiconductor device according to the first preferred embodiment taken along a line A-A′ in FIG. 1;

FIG. 3 is a top view illustrating a semiconductor device according to a first modification of the first preferred embodiment;

FIG. 4 is a sectional view illustrating the semiconductor device according to the first modification of the first preferred embodiment taken along the line A-A′ in FIG. 1;

FIG. 5 is a top view illustrating a semiconductor device according to a second modification of the first preferred embodiment;

FIG. 6 is a sectional view illustrating the semiconductor device taken along a line A-A′ in FIG. 5;

FIG. 7 is a top view illustrating a semiconductor device according to a third modification of the first preferred embodiment;

FIG. 8 is a sectional view illustrating the semiconductor device taken along a line A-A′ in FIG. 7;

FIG. 9 is a top view illustrating a semiconductor device according to a fourth modification of the first preferred embodiment;

FIG. 10 is a sectional view illustrating the semiconductor device taken along a line A-A′ in FIG. 9;

FIG. 11 is a top view illustrating a semiconductor device according to a fifth modification of the first preferred embodiment;

FIG. 12 is a sectional view illustrating the semiconductor device taken along a line A-A′ in FIG. 11;

FIG. 13 is a top view illustrating a semiconductor device according to a second preferred embodiment;

FIG. 14 is a top view illustrating a semiconductor device according to a first modification of the second preferred embodiment;

FIG. 15 is a top view illustrating a semiconductor device according to a third preferred embodiment;

FIG. 16 is a sectional view illustrating the semiconductor device taken along a line A-A′ in FIG. 15;

FIG. 17 is a top view illustrating a semiconductor device according to a fourth preferred embodiment;

FIG. 18 is a top view illustrating a semiconductor device according to a first modification of the fourth preferred embodiment;

FIG. 19 is a top view illustrating a semiconductor device according to a fifth preferred embodiment; and

FIG. 20 is a top view illustrating a semiconductor device according to a sixth preferred embodiment.

### DESCRIPTION OF THE PREFERRED EMBODIMENTS

In the following description, an N type and a P type represent a conductivity type of a semiconductor. An N+ type indicates that an N type impurity concentration is higher than that of the N type.

### A. First Preferred Embodiment

### A-1. Configuration

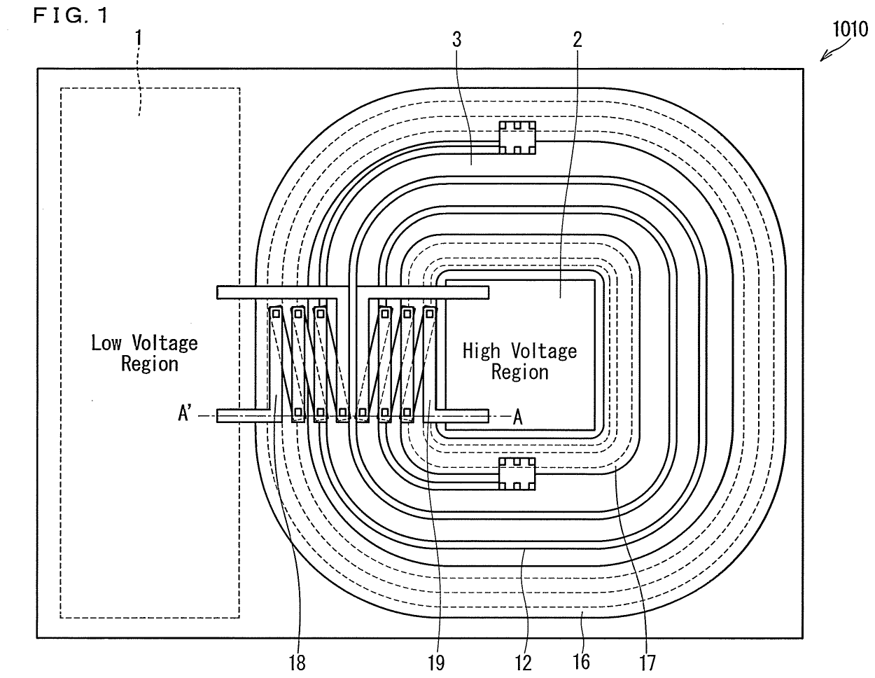

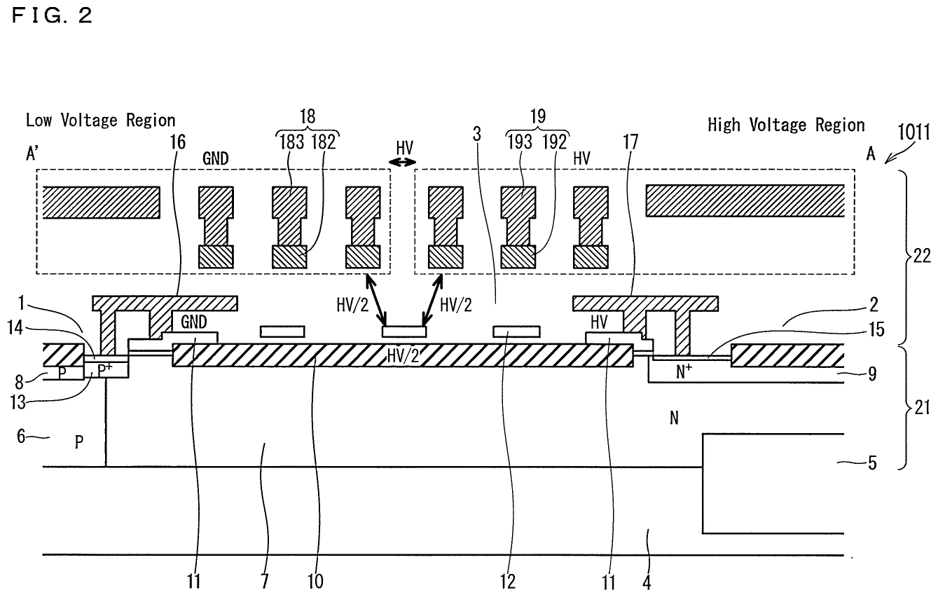

FIG. 1 is a top view illustrating a semiconductor device 1010 according to a first preferred embodiment. FIG. 2 is a sectional view illustrating the semiconductor device 1010 taken along a line A-A′ in FIG. 1. Hereinafter, a configuration of the semiconductor device 1010 will be described using these drawings.

The semiconductor device 1010 is a high voltage integrated circuit (HVIC) chip that drives and controls a power device. At this point, for example, the power device is an insulated gate bipolar transistor (IGBT), a power metal-oxide-semiconductor field-effect transistor (MOSFET), or the like.

As illustrated in FIG. 1, the semiconductor device 1010 is divided into three regions of a low potential region 1, a high potential region 2, and a high-withstand-voltage isolation region 3 in plan view. The high-withstand-voltage isolation region 3 is provided between the low potential region 1 and the high potential region 2, and electrically separates the low potential region 1 and the high potential region 2. In the example of FIG. 1, the high-withstand-voltage isolation region 3 is formed to surround the high potential region 2.

The low potential region 1 has a ground (GND) as a reference potential. The high potential region 2 has a floating voltage electrically separated from the GND as a reference voltage.

As illustrated in FIG. 2, the semiconductor device 1010 includes a P type substrate 4 that is a semiconductor substrate, an element structure 21 formed on the P type substrate 4, and a metal structure 22 including three layers of metal wirings formed on the element structure 21.

The element structure 21 includes an N+ type buried layer 5, a P type well layer 6, an N type well layer 7, a P type inversion preventing layer 8, an N type inversion preventing layer 9, an element-isolation LOCOS oxide film 10, a doped polysilicon electrode 11, a high-resistance polysilicon field plate 12, a P type body region 13, a P type contact region 14, and an N type contact region 15.

The N+ type buried layer 5 is provided on the P type substrate 4 in the high potential region 2 by ion implantation.

The P type well layer 6 and the N type well layer 7 are formed by performing epitaxial growth on the P type substrate 4 and the N+ type buried layer 5 and further performing ion implantation. The P type well layer 6 is formed on the P type substrate 4 in the low potential region 1. The N type well layer 7 is formed on the P type substrate 4 in the high-withstand-voltage isolation region 3 and on the N+ type buried layer 5 in the high potential region 2. The N type well layer 7 is a RESURF layer. That is, the high-withstand-voltage isolation region 3 has a RESURF separation structure. Either the P type well layer 6 or the N type well layer 7 may use an epitaxial growth layer as it is.

The P type inversion preventing layer 8, the N type inversion preventing layer 9, and the element-isolation LOCOS oxide film 10 are formed by ion-implanting ions into the epitaxial growth layer and then performing thermal oxidation processing. The P type inversion preventing layer 8 is formed on the P type well layer 6 in the low potential region 1. The N type inversion preventing layer 9 is formed on the N type well layer 7 in the high potential region 2. The element-isolation LOCOS oxide film 10 is formed on the N type well layer 7 in the high-withstand-voltage isolation region 3.

In order to stabilize a potential gradient of the N type well layer 7, the doped polysilicon electrode 11 is formed on the N type well layer 7, and the high-resistance polysilicon field plate 12 is formed on the element-isolation LOCOS oxide film 10 on the N type well layer 7. As described above, the element structure 21 of the high-withstand-voltage isolation region 3 has a resistive field plate.

The P type body region 13, the P type contact region 14, and the N type contact region 15 are formed for connection with the P type substrate 4. The P type body region 13 is formed on the P type well layer 6, and the P type contact region 14 is formed on the P type body region 13. The N type contact region 15 is formed on the N type inversion preventing layer 9. The above is the configuration of the element structure 21.

In the first preferred embodiment, the metal structure 22 includes three layers of metal wirings. The metal wiring of the first layer configures aluminum wiring field plates 16, 17. The aluminum wiring field plate 16 is formed on a side of the low potential region 1 in the high-withstand-voltage isolation region 3, and is in contact with the doped polysilicon electrode 11 and the P type contact region 14. The aluminum wiring field plate 17 is formed on the side of the high potential region 2 in the high-withstand-voltage isolation region 3, and is in contact with the doped polysilicon electrode 11 and the N type contact region 15.

As illustrated in FIG. 1, one end of the high-resistance polysilicon field plate 12 is connected to the low potential region 1 through the aluminum wiring field plate 16. In addition, the high-resistance polysilicon field plate 12 spirally goes around the high-withstand-voltage isolation region 3, and the other end of the high-resistance polysilicon field plate 12 is connected to the high potential region 2 through the aluminum wiring field plate 17.

The metal wiring of the second layer includes a metal wiring 182 of the second layer provided on the side of the low potential region 1 of the high-withstand-voltage isolation region 3 and a metal wiring 192 of the second layer provided on the side of the high potential region 2 of the high-withstand-voltage isolation region 3. The metal wiring of the third layer includes a metal wiring 183 of the third layer provided on the side of the low potential region 1 of the high-withstand-voltage isolation region 3 and a metal wiring 193 of the third layer provided on the side of the high potential region 2 of the high-withstand-voltage isolation region 3.

The metal wiring 182 of the second layer and the metal wiring 183 of the third layer configure a lateral primary coil 18. The primary coil 18 is provided on the side of the low potential region 1 of the high-withstand-voltage isolation region 3. The metal wiring 192 of the second layer and the metal wiring 193 of the third layer configure a lateral secondary coil 19. The secondary coil 19 is provided on the side of the high potential region 2 of the high-withstand-voltage isolation region 3. The lateral types of the primary coil 18 and the secondary coil 19 mean that coil axes of the primary coil 18 and the secondary coil 19 are parallel to a plane direction of the P type substrate 4. The primary coil 18 is connected to the low potential region 1, and the secondary coil 19 is connected to the high potential region 2.

As illustrated in FIG. 1, the coil axis of the primary coil 18 and the coil axis of the secondary coil 19 are opposed to each other. That is, the coil axis of the secondary coil 19 exists on an extension line of the coil axis of the primary coil 18. Thus, the primary coil 18 and the secondary coil 19 are magnetically coupled by magnetism on the coil axis. That is, the primary coil 18 is a primary-side element, the secondary coil 19 is a secondary-side element, and the primary coil 18 and the secondary coil 19 function as a signal transmission element in a pair.

The semiconductor device 1010 described above includes the P type substrate 4 that is the semiconductor substrate and the element structure 21 formed on the P type substrate 4. In plan view, the semiconductor device is divided into the low potential region 1 having GND as the reference potential, the high potential region 2 having a floating potential as the reference potential, and the high-withstand-voltage isolation region 3 provided between the low potential region 1 and the high potential region 2 to insulate the low potential region 1 and the high potential region 2 from each other. The semiconductor device 1010 includes the signal transmission element provided on the element structure 21 in the high-withstand-voltage isolation region 3. The signal transmission element includes the primary-side element that is provided on the side of the low potential region 1 of the high-withstand-voltage isolation region 3 and connected to the low potential region 1, and the secondary-side element that is provided on the side of the high potential region 2 of the high-withstand-voltage isolation region 3 and connected to the high potential region 2. The primary-side element and the secondary-side element are magnetically coupled to each other by a magnetic field in a direction parallel to the main surface of the P type substrate 4.

In the semiconductor device 1010, the primary-side element is the primary coil 18 that is a lateral coil having a coil axis in the direction parallel to the main surface of the P type substrate 4. The secondary side coupling element is the secondary coil 19 that is the lateral coil having the coil axis in the direction parallel to the main surface of the P type substrate 4. The primary coil 18 and the secondary coil 19 are magnetically coupled to each other by the magnetic field in the direction parallel to the main surface of the P type substrate 4.

According to the semiconductor device 1010 described above, the following effects can be obtained. A maximum potential difference HV between the primary coil 18 and the secondary coil 19 is, for example, 600 V or 1200 V. However, the primary coil 18 and the secondary coil 19 are the lateral type, so that a withstand voltage between the primary coil 18 and the secondary coil can relatively easily be secured when a distance between the primary coil 18 and the secondary coil 19 is secured by a layout pattern.

In addition, because both the primary coil 18 and the secondary coil 19 are disposed on the high-withstand-voltage isolation region 3, a potential difference in a vertical direction, namely, a thickness direction of the P type substrate 4 is reduced. For example, in a conventional structure in which both the primary coil 18 and the secondary coil 19 are provided in the low potential region 1, the maximum potential difference in the vertical direction between a lead-out wiring of the secondary coil 19 and the high-resistance polysilicon field plate 12 is HV.

On the other hand, in the semiconductor device 1010, the maximum potential difference in the vertical direction between the primary coil 18 and the high-resistance polysilicon field plate 12 is HV/2, and the maximum potential difference in the vertical direction between the secondary coil 19 and the high-resistance polysilicon field plate 12 is also HV/2. In this manner, the potential difference in the vertical direction is halved from that in the conventional structure. As a result, the thickness of the inter-wiring interlayer film can be reduced, and the process cost is reduced.

In the semiconductor device 1010, because the primary coil 18 and the secondary coil 19 are provided in the high-withstand-voltage isolation region 3 that is an ineffective region, an increase in the ineffective region due to the provision of the primary coil 18 and the secondary coil 19 is not generated. Accordingly, a chip size can be reduced as compared with the conventional structure.

### A-2. First Modification

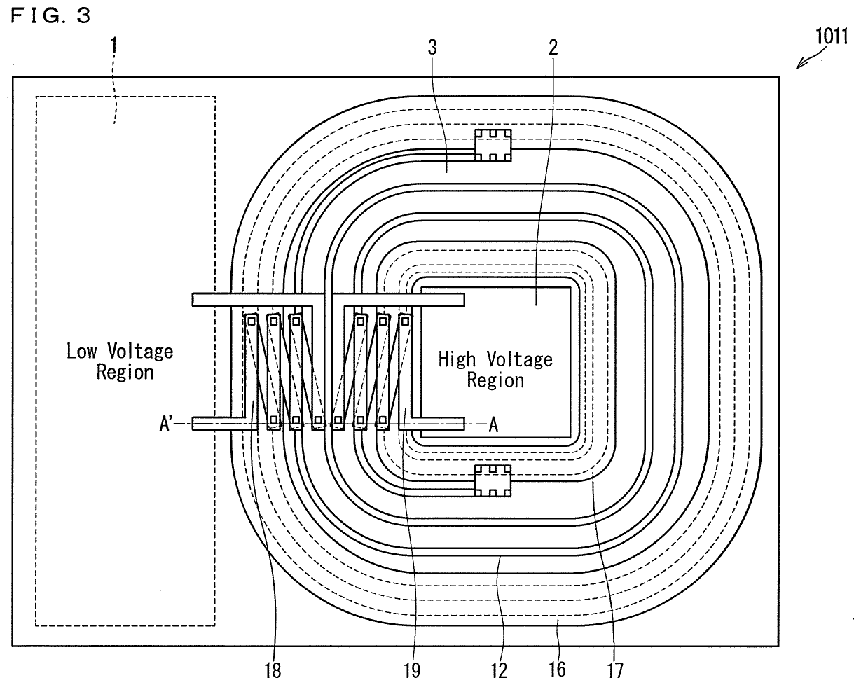

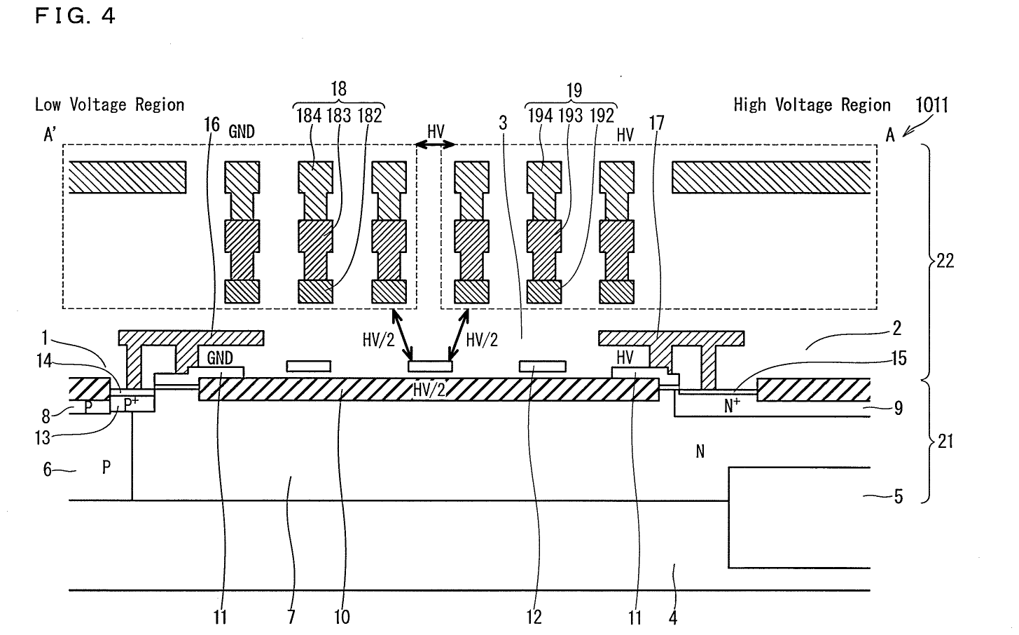

FIG. 3 is a top view illustrating a semiconductor device 1011 according to a first modification of the first preferred embodiment. FIG. 4 is a sectional view illustrating the semiconductor device 1011 taken along a line A-A′ in FIG. 3. Hereinafter, the configuration of the semiconductor device 1011 will be described using these drawings.

The semiconductor device 1011 differs from the semiconductor device 1010 only in the metal structure 22. The metal structure 22 in the semiconductor device 1011 includes N layers of metal wirings. Here, N is a natural number at least 4.

In the example of FIG. 4, the metal structure 22 includes four layers of metal wirings. The metal wiring of the fourth layer includes a metal wiring 184 of the fourth layer provided on the side of the low potential region 1 of the high-withstand-voltage isolation region 3 and a metal wiring 194 of the fourth layer provided on the side of the high potential region 2 of the high-withstand-voltage isolation region 3.

The metal wiring 182 of the second layer and the metal wiring 184 of the fourth layer configure the lateral primary coil 18. The metal wiring 192 of the second layer and the metal wiring 194 of the fourth layer configure the lateral secondary coil 19. The metal wiring 183 of the third layer vertically connects the metal wiring 182 of the second layer and the metal wiring 184 of the fourth layer that configure the primary coil 18. Similarly, the metal wiring 193 of the third layer vertically connects the metal wiring 192 of the second layer and the metal wiring 194 of the fourth layer that configure the secondary coil 19.

In the example of FIG. 4, the metal structure 22 includes four layers of metal wirings, and the lateral coils are vertically connected by the third layer of the metal wiring. In the case where the metal structure 22 includes five layers of metal wiring, the lateral coil may be vertically connected by the third layer and the fourth layer of the metal wirings.

That is, the semiconductor device 1011 includes N-layer metal wiring formed on the element structure 21 with N as a natural number at least 4. The lateral coil includes the metal wirings of the second layer and an Nth layer. The metal wirings of the second layer and the Nth layer configuring one lateral coil are vertically connected by the metal wirings of the third layer to the (N−1)th layer. Thus, sectional areas of the primary coil 18 and the secondary coil 19 are increased, and magnetic coupling strength between the primary coil 18 and the secondary coil 19 is improved.

However, because the number of wiring layers increases and the process cost increases, the configuration of the semiconductor device 1011 is preferably applied in the case where multilayer wiring is required in another circuit region or in the case where improvement of the magnetic coupling strength is required for securing an operation margin of signal transmission or the like.

### A-3. Second Modification

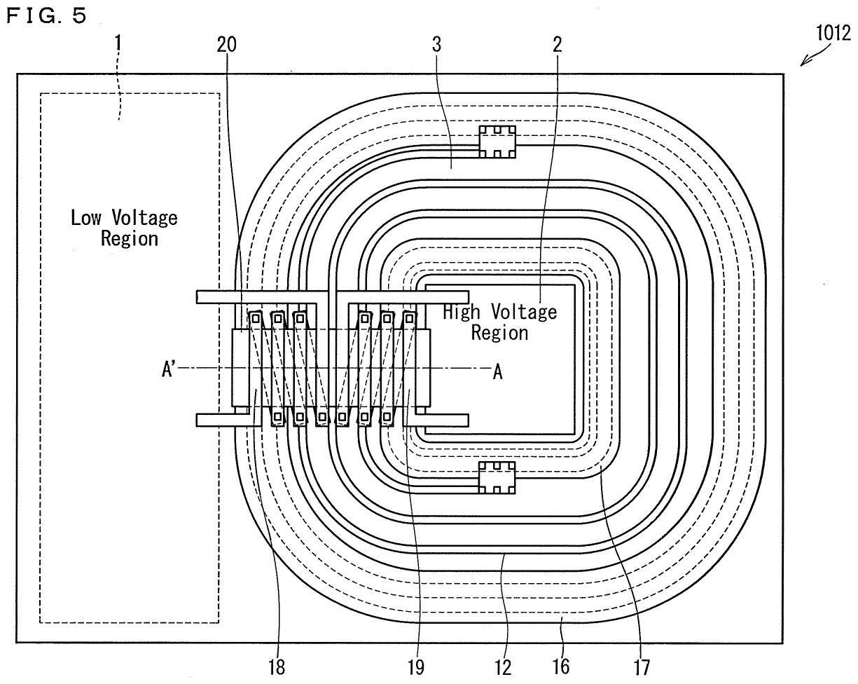

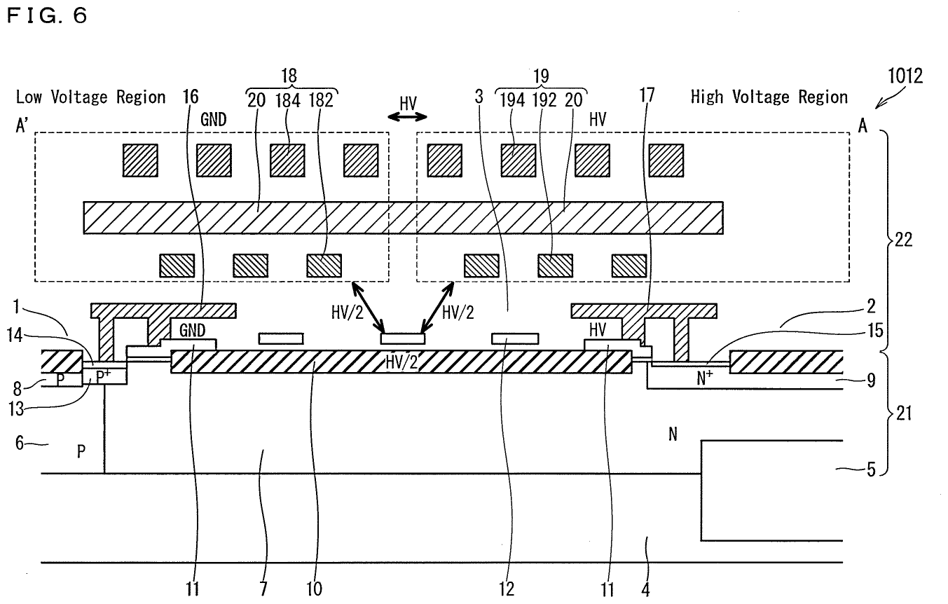

FIG. 5 is a top view illustrating a semiconductor device 1012 according to a second modification of the first preferred embodiment. FIG. 6 is a sectional view illustrating the semiconductor device 1012 taken along a line A-A′ in FIG. 5. Hereinafter, the configuration of the semiconductor device 1012 will be described using these drawings.

In the semiconductor device 1012, in the configuration of the semiconductor device 1011, the metal wirings from the third layer to the (N−1)th layer are made of a magnetic material, and inserted into the primary coil 18 and the secondary coil 19 made of metal wirings of the second layer and the Nth layer in a flat plate shape to form a coil core 20.

FIG. 6 illustrates the case where the metal structure 22 includes four layers of metal wirings. In this example, the metal wiring of the third layer is inserted into the primary coil 18 and the secondary coil 19 to form the coil core 20.

That is, the semiconductor device 1012 includes N-layer metal wirings formed on the element structure with N as a natural number at least 4, the lateral coil is formed of the second layer and the Nth layer metal wirings, and the metal wirings of the third to (N−1)th layers are formed of the magnetic material, and configure the coil core 20 of the lateral coil. With the above configuration, the magnetic coupling strength between the primary coil 18 and the secondary coil 19 is improved.

As the magnetic material used for the coil core 20, cobalt is suitable because cobalt is put to practical use as a semiconductor wiring material. Nevertheless, in addition to cobalt, nickel may be used, or cobalt or an alloy of nickel may be used.

However, because the number of wiring layers increases and the process cost increases, the configuration of the semiconductor device 1012 is preferably applied in the case where multilayer wiring is required in another circuit region or in the case where improvement of the magnetic coupling strength is required for securing an operation margin of signal transmission or the like.

### A-4. Third Modification

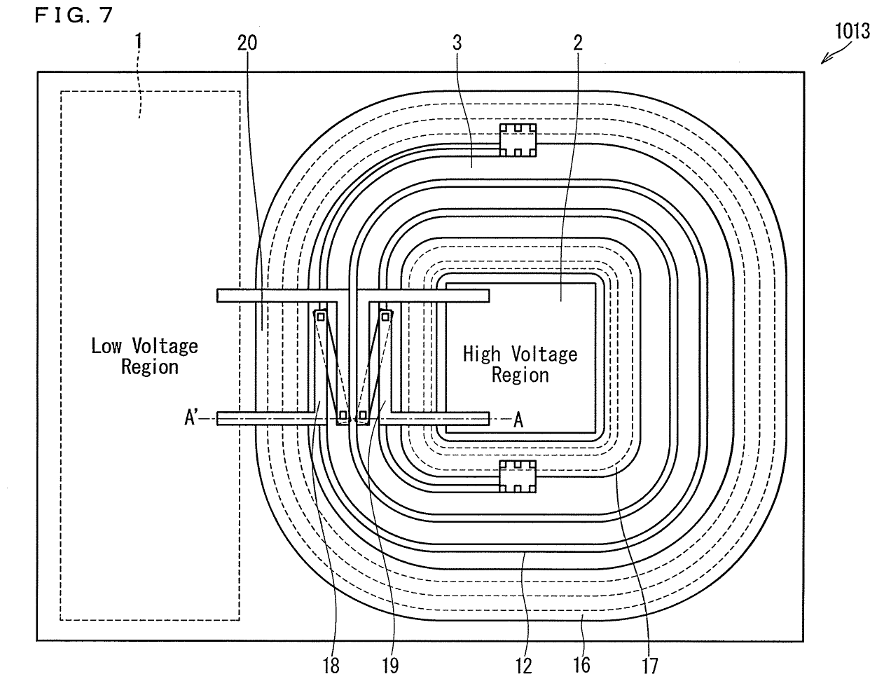

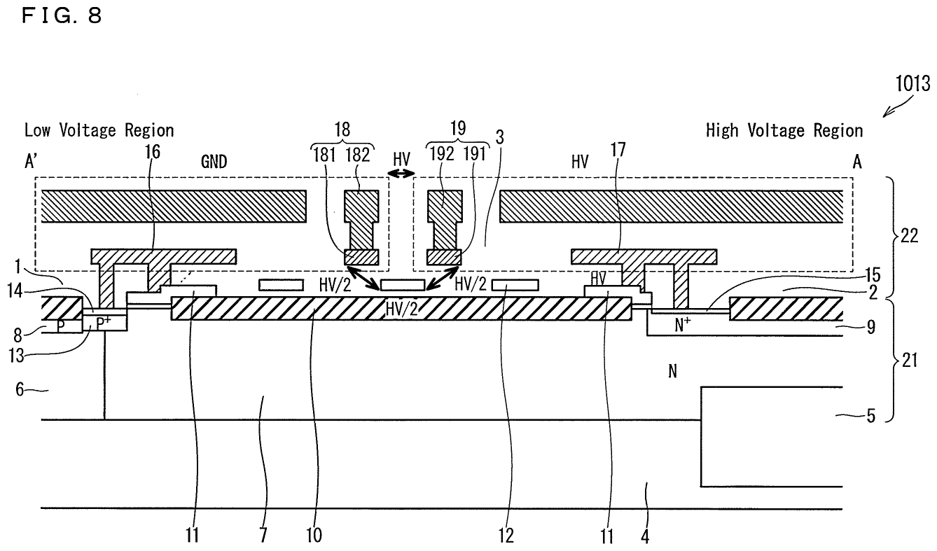

FIG. 7 is a top view illustrating a semiconductor device 1013 according to a third modification of the first preferred embodiment. FIG. 8 is a sectional view illustrating the semiconductor device 1013 taken along a line A-A′ in FIG. 7. Hereinafter, the configuration of the semiconductor device 1013 will be described using these drawings.

The semiconductor device 1013 differs from the semiconductor device 1010 only in the metal structure 22. The metal structure 22 in the semiconductor device 1013 includes two layers of metal wirings. In addition to the aluminum wiring field plates 16, 17, the metal wiring of the first layer includes a metal wiring 181 of the first layer configuring the primary coil 18 and a metal wiring 191 of the first layer configuring the secondary coil 19. That is, the metal wirings 181, 191 of the first layer are an aluminum wiring.

The metal wiring 181 of the first layer and the metal wiring 182 of the second layer configure the primary coil 18. In addition, the metal wiring 191 of the first layer and the metal wiring 192 of the second layer configure the secondary coil 19.

That is, the semiconductor device 1013 includes two layers of metal wirings formed on the element structure 21, and the lateral coil includes the first layer and the second layer of metal wirings. According to the semiconductor device 1013, because the metal structure 22 includes two layers of metal wiring fewer than those of the other semiconductor devices 1010, 1011, 1012 described above, the process cost is reduced. However, the lower layer wiring of the lateral coil needs to be formed of aluminum wiring of the same layer as the aluminum wiring field plates 16, 17. For this reason, the region where the lateral coil can be formed is narrow, the number of windings of the coil is reduced, and the magnetic coupling strength is weakened. In addition, because the distance in the vertical direction between the primary coil 18 and the secondary coil 19 and the high-resistance polysilicon field plate 12 becomes short, electric field strength increases and the withstand voltage decreases. However, in the case where the necessary withstand voltage and the operation margin of signal transmission are still secured, the semiconductor device 1013 is the least expensive and preferable aspect.

### A-5. Fourth Modification

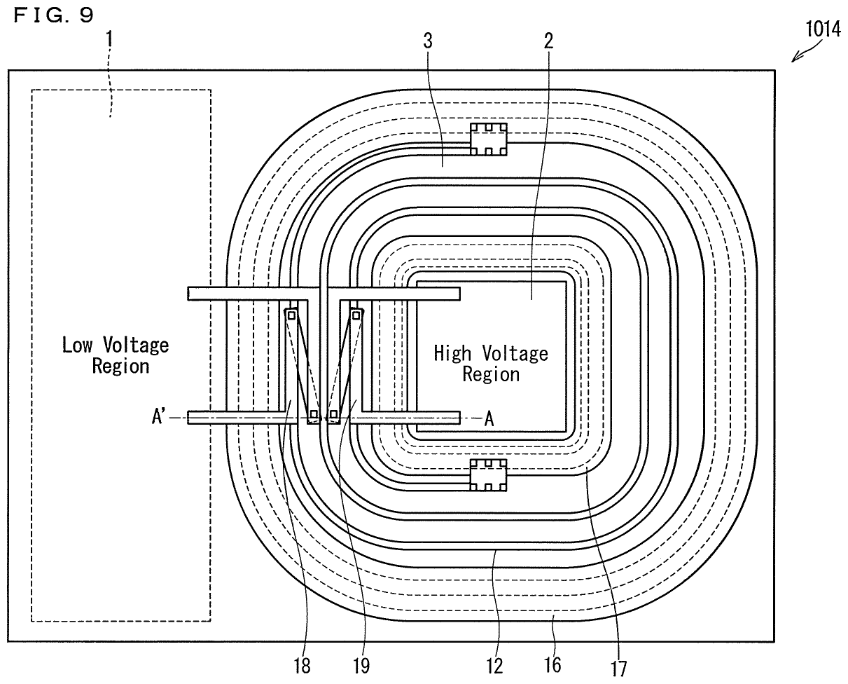

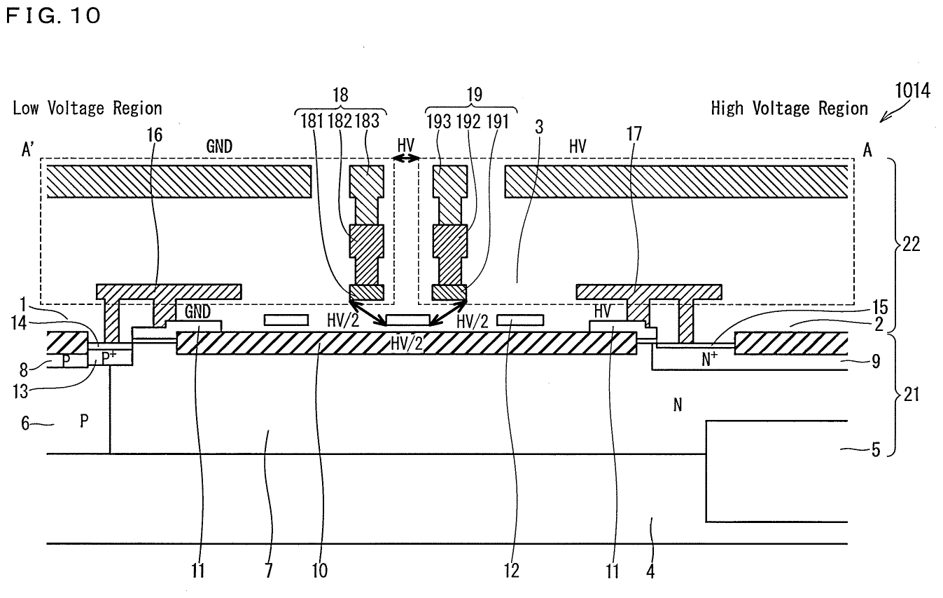

FIG. 9 is a top view illustrating a semiconductor device 1014 according to a fourth modification of the first preferred embodiment. FIG. 10 is a sectional view illustrating the semiconductor device 1014 taken along a line A-A′ in FIG. 9. Hereinafter, the configuration of the semiconductor device 1014 will be described using these drawings.

The semiconductor device 1014 is different from the semiconductor device 1013 in that the metal structure 22 includes N layers of metal wirings. Here, N is a natural number at least 3.

In the example of FIG. 10, the metal structure 22 includes three layers of metal wirings. The metal wiring 181, 191 of the first layer has the configuration similar to that of the semiconductor device 1013. The metal wiring 181 of the first layer and the metal wiring 183 of the third layer configure the lateral primary coil 18. The metal wiring 191 of the first layer and the metal wiring 193 of the third layer constitute the lateral secondary coil 19. The metal wiring 182 of the second layer vertically connects the metal wiring 181 of the first layer and the metal wiring 183 of the third layer that configure the primary coil 18. Similarly, the metal wiring 192 of the second layer vertically connects the metal wiring 191 of the first layer and the metal wiring 193 of the third layer that configure the secondary coil 19.

In the example of FIG. 10, the metal structure 22 includes three layers of metal wirings, and the lateral coils are vertically connected by the second layer of metal wiring. In the case where the metal structure 22 includes four layers of metal wiring, the lateral coil may be vertically connected by the second layer and third layer of metal wirings. That is, when the N-layer metal wiring is used, the lateral coils may be vertically connected by the metal wirings from the second layer to the (N−1)th layer.

That is, the semiconductor device 1014 includes N-layer metal wiring formed on the element structure 21 with N as a natural number at least 3. The lateral coil includes the metal wirings of the first layer and the Nth layer. The metal wirings of the second layer and the Nth layer configuring one lateral coil are vertically connected by the metal wirings of the second layer to the (N−1)th layer. With the above configuration, the effect that the sectional areas of the primary coil 18 and the secondary coil 19 increase to improve the magnetic coupling strength between the primary coil 18 and the secondary coil 19 can be obtained. The structure of the semiconductor device 1014 can be optimized depending on the number of wiring layers as a process, the layout restriction, or the like.

### A-6. Fifth Modification

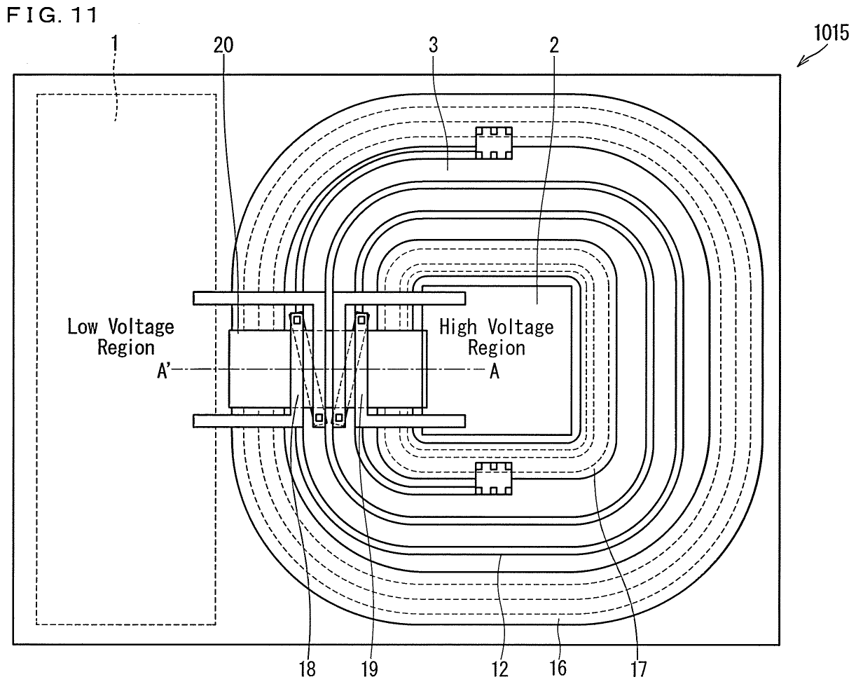

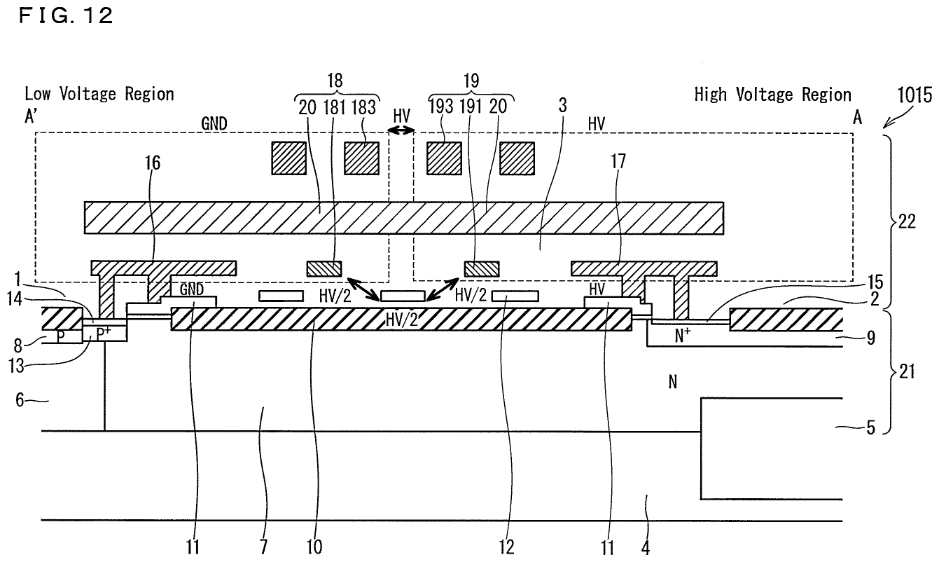

FIG. 11 is a top view illustrating a semiconductor device 1015 according to a fifth modification of the first preferred embodiment. FIG. 12 is a sectional view illustrating the semiconductor device 1015 taken along a line A-A in FIG. 11. Hereinafter, the configuration of the semiconductor device 1015 will be described using these drawings.

In the semiconductor device 1015, in the configuration of the semiconductor device 1014, the metal wirings from the second layer to the (N−1)th layer are made of the magnetic material, and inserted into the primary coil 18 and the secondary coil 19 that are made of the metal wirings of the first layer and the Nth layer in a flat plate shape to form the coil core 20.

FIG. 12 illustrates the case where the metal structure 22 includes three layers of metal wirings. In this example, the metal wiring of the second layer is inserted into the primary coil 18 and the secondary coil 19 to form the coil core 20.

That is, the semiconductor device 1015 includes N-layer metal wiring formed on the element structure with N as a natural number at least 3. The lateral coil includes the metal wirings of the first layer and the Nth layer. The metal wirings of the second layer to the (N−1)th layer are made of the magnetic material and configure the coil core of the lateral coil. With the above configuration, the magnetic coupling strength between the primary coil 18 and the secondary coil 19 is improved. The structure of the semiconductor device 1015 can be optimized depending on the number of wiring layers as the process, the layout restriction, or the like.

### B. Second Preferred Embodiment

### B-1. Configuration

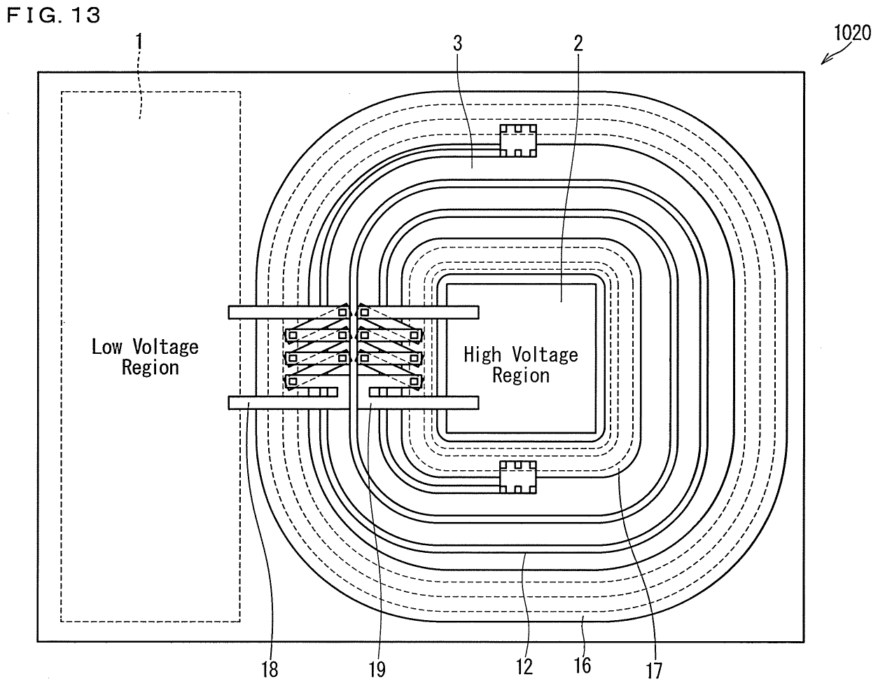

FIG. 13 is a top view illustrating a semiconductor device 1020 according to a second preferred embodiment. The semiconductor device 1020 is different from the semiconductor device 1010 according to the first preferred embodiment only in that the primary coil 18 and the secondary coil 19 are disposed such that the coil axes of the primary coil 18 and the secondary coil 19 are parallel to each other.

In the semiconductor device 1020, the primary coil 18 and the secondary coil 19 are magnetically coupled not on the coil axes of the primary coil 18 and the secondary coil 19 but by magnetic fluxes around the coils of the primary coil 18 and the secondary coil 19. The magnetic flux density around the coil is lower than the magnetic flux density on the coil axis. However, because the coil axes of the primary coil 18 and the secondary coil 19 are parallel to a circumferential direction of the high-withstand-voltage isolation region 3, there is an advantage that the coil lengths of the primary coil 18 and the secondary coil 19 can be easily increased and the number of windings can be increased.

### B-2. Modification

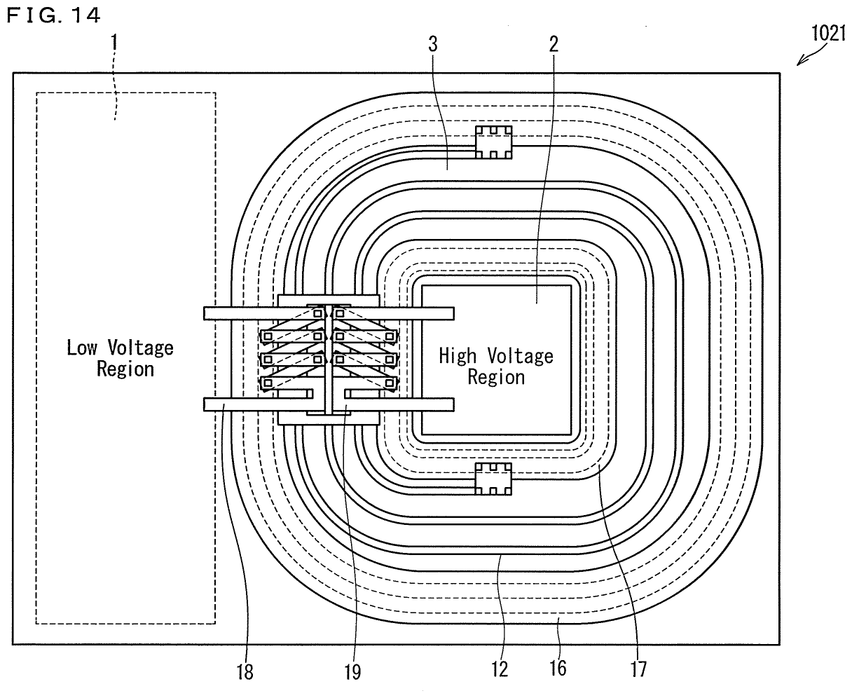

FIG. 14 is a top view illustrating a semiconductor device 1021 according to a modification of the second preferred embodiment. In the semiconductor device 1021, in the semiconductor device 1020, the metal structure 22 is configured by at least four N-layer metal wirings, and the coil core 20 is formed by the metal wirings of the third to (N−1)th layers. In other words, in the semiconductor device 1021, the disposition in which the coil axes of the primary coil 18 and the secondary coil 19 are parallel to each other is applied to the semiconductor device 1012 according to the second modification of the first preferred embodiment.

According to the configuration of the semiconductor device 1021, the number of windings of the coil can be increased and the primary coil 18 and the secondary coil 19 are magnetically coupled by the magnetic flux on the coil axis through the coil core 20, so that the high magnetic coupling strength can be obtained.

### C. Third Preferred Embodiment

### C-1. Configuration

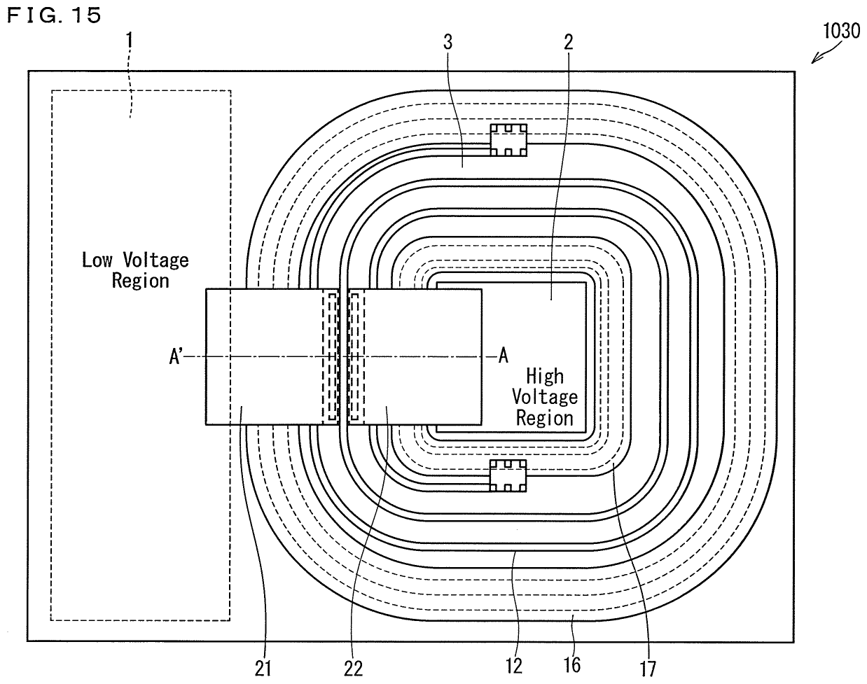

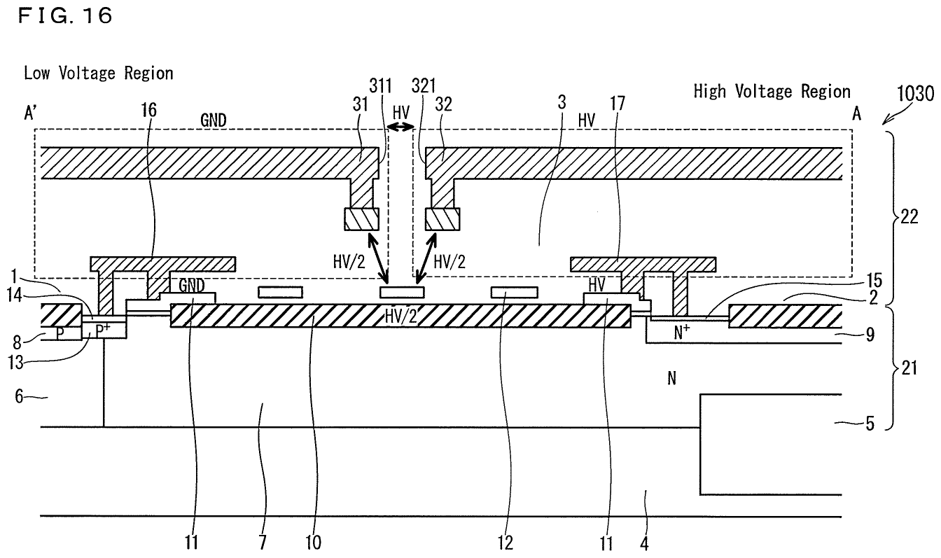

FIG. 15 is a top view illustrating a semiconductor device 1030 according to a third preferred embodiment. FIG. 16 is a sectional view illustrating the semiconductor device 1030 taken along a line A-A′ in FIG. 15. Hereinafter, the configuration of the semiconductor device 1030 will be described using these drawings.

The metal structure 22 of the semiconductor device 1030 includes a primary plate electrode 31 that is provided on the side of the low potential region 1 of the high-withstand-voltage isolation region 3 and connected to the low potential region 1, and a secondary plate electrode 32 that is provided on the side of the high potential region 2 of the high-withstand-voltage isolation region 3 and connected to the high potential region 2. The primary plate electrode 31 corresponds to the primary-side element, and the secondary plate electrode 32 corresponds to the secondary-side element.

The primary plate electrode 31 has a first surface 311 parallel to the thickness direction of the P type substrate 4. The secondary plate electrode 32 has a second surface 321 that is parallel to the thickness direction of the P type substrate 4 and is opposite to the first surface 311. The primary plate electrode 31 and the secondary plate electrode 32 are capacitively coupled to each other by an electric field between the first surface 311 and the second surface 321, thereby performing the signal transmission.

That is, in the semiconductor device 1030, the primary-side element is the primary plate electrode 31 having the first surface 311 parallel to the thickness direction of the P type substrate 4. The secondary-side element is the secondary plate electrode 32 having the second surface 321 that is parallel to the thickness direction of the P type substrate 4 and is opposite to the first surface 311. The primary plate electrode 31 and the secondary plate electrode 32 are capacitively coupled to each other by the electric field between the first surface 311 and the second surface 321 in the direction parallel to the main surface of the P type substrate 4.

According to the above configuration, the potential difference in the vertical direction between the primary plate electrode 31 and the high-resistance polysilicon field plate 12 is HV/2. In addition, the potential difference in the vertical direction between the secondary plate electrode 32 and the high-resistance polysilicon field plate 12 is also HV/2. That is, similarly to the first and second embodiments in which the lateral coil is used for the capacitive coupling element, the potential difference in the vertical direction is reduced by half from that in the conventional structure. Accordingly, the thickness of the inter-wiring interlayer film can be reduced, and the process cost is reduced.

### C-2. Modification

Although not illustrated, the capacitance value may be increased by meandering the first surface 311 and the second surface 321, which are capacitance forming surfaces between the primary plate electrode 31 and the secondary plate electrode 32, to form a comb-shaped meshing pattern. However, in this case, because the electric field intensity in the vertical direction increases at a convex portion of each comb tooth, it is necessary to determine the pattern while balancing with the securing of the withstand voltage.

In the first to third embodiments, the signal transmission element is provided only on one of the four sides of the high-withstand-voltage isolation region 3. However, the signal transmission element may be provided on at least two sides of the high-withstand-voltage isolation region 3, or may be provided on the entire surface including an arc portion of the high-withstand-voltage isolation region 3. Thus, the magnetic coupling strength or the capacitive coupling strength can be increased. Alternatively, a plurality of pairs of signal transmission elements can be provided.

### D. Fourth Preferred Embodiment

### D-1. Configuration

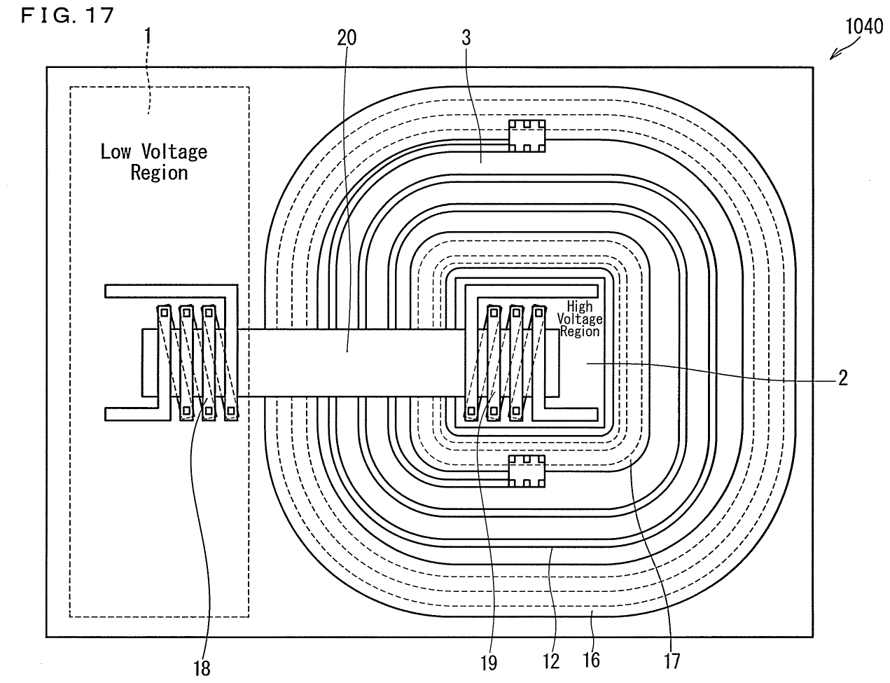

FIG. 17 is a top view illustrating a semiconductor device 1040 according to a fourth preferred embodiment. In the semiconductor device 1040, in the semiconductor device 1012 according to the second modification of the first preferred embodiment, the primary coil 18 is disposed in the low potential region 1 and the secondary coil 19 is disposed in the high potential region 2.

The metal wirings from the third layer to the (N−1)th layer are made of the magnetic material, and inserted into the primary coil 18 and the secondary coil 19 in a flat plate shape from the low potential region 1 to the high potential region 2 to form the coil core 20. The coil core 20 ensures the magnetic coupling strength.

That is, in the semiconductor device 1040, the signal transmission element includes the primary coil 18 provided in the low potential region 1, the secondary coil 19 provided in the high potential region 2, and the coil core 20 made of the magnetic material inserted into both the primary coil 18 and the secondary coil 19 across the high-withstand-voltage isolation region 3. According to the above configuration, because the primary coil 18 and the secondary coil 19 that are the signal transmission elements are disposed on the circuit area, the chip size increases. However, the potential difference in the vertical direction between the lateral coil and the high-resistance polysilicon field plate 12 is eliminated, so that the thickness of the interlayer oxide film and the process cost can be reduced.

### D-2. Modification

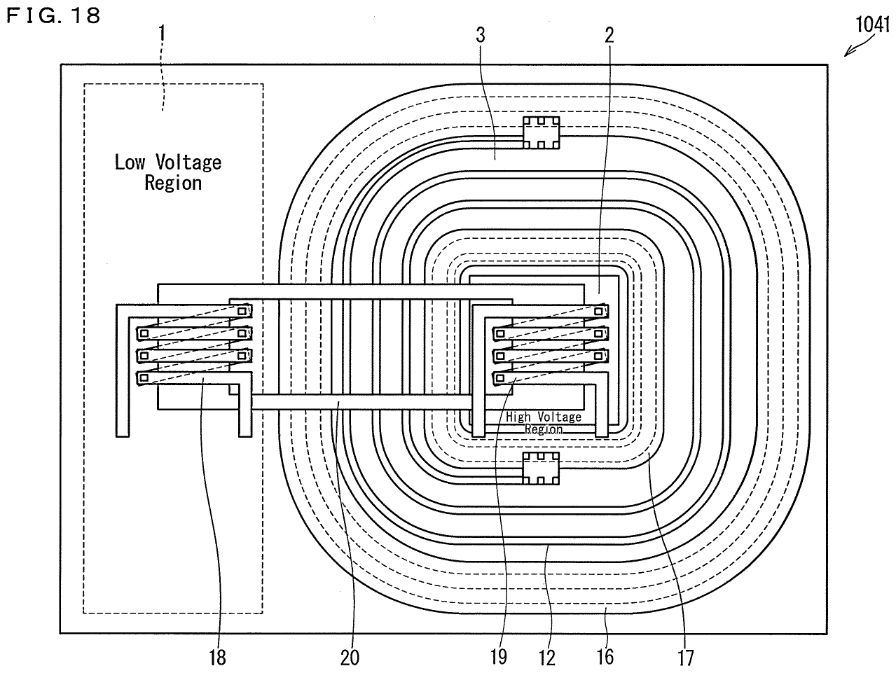

FIG. 18 is a top view illustrating a semiconductor device 1041 according to a modification of the fourth preferred embodiment. In the semiconductor device 1040, the primary coil 18 and the secondary coil 19 are disposed such that the coil axes of the primary coil 18 and the secondary coil 19 are opposite to each other. On the other hand, in the semiconductor device 1041, the primary coil 18 and the secondary coil 19 are disposed such that the coil axes of the primary coil 18 and the secondary coil 19 are parallel to each other.

### E. Fifth Preferred Embodiment

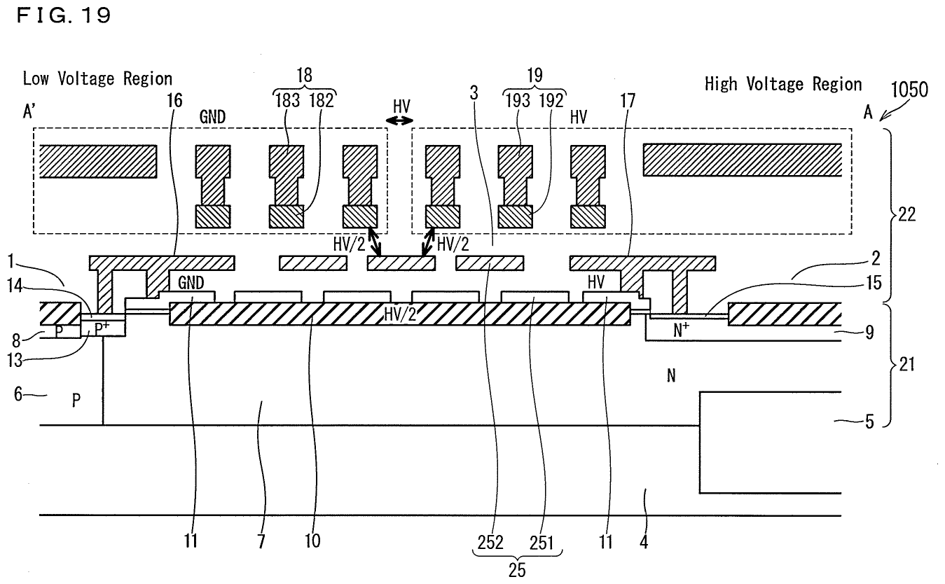

FIG. 19 is a sectional view illustrating a semiconductor device 1050 according to a fifth preferred embodiment. The section illustrated in FIG. 19 corresponds to the section of the semiconductor device 1010 illustrated in FIG. 2.

In the semiconductor device 1010 according to the first preferred embodiment, the semiconductor device 1050 uses a capacitive coupling type field plate 25 instead of the high-resistance polysilicon field plate 12.

The element structure 21 of the semiconductor device 1050 includes a lower field plate 251 on the same layer as the doped polysilicon electrode 11 in the high-withstand-voltage isolation region 3. The metal structure 22 of the semiconductor device 1050 includes three layers of metal wirings, and the metal wiring of the first layer includes an upper field plate 252 in addition to the aluminum wiring field plates 16, 17. That is, the upper field plate 252 is made of aluminum wiring.

The lower field plate 251 and the upper field plate 252 configure the capacitive coupling type field plate 25. According to the semiconductor device 1050, because the aluminum wiring is used for the upper field plate 252, the electric field strength in the vertical direction increases. However, when the RESURF separation distance is short and the high-resistance polysilicon field plate 12 is used, the present structure is preferably applied in the case of not being suitable due to an increased leakage current and increased power consumption.

The configuration of the present embodiment in which the capacitive coupling type field plate 25 is used can also be applied to a semiconductor device in which the metal wiring of the first layer is not used as the lateral coil among the various semiconductor devices described above.

### F. Sixth Preferred Embodiment

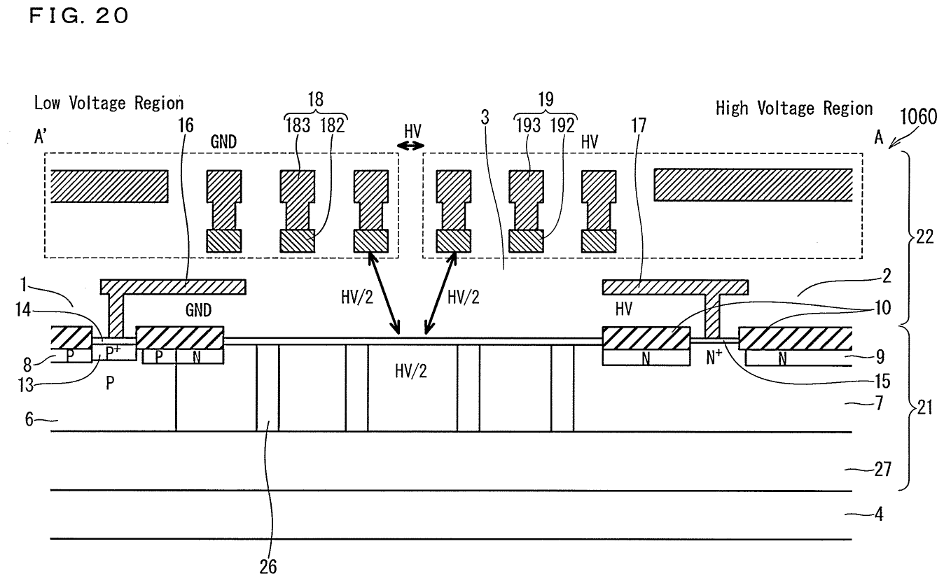

FIG. 20 is a sectional view illustrating a semiconductor device 1060 according to a sixth preferred embodiment. The section illustrated in FIG. 20 corresponds to the section of the semiconductor device 1010 illustrated in FIG. 2.

The semiconductor device 1060 includes an isolation structure (hereinafter, a trench isolation structure) by a trench 26 instead of the junction isolation structure in the semiconductor device 1010 according to the first preferred embodiment. The trench 26 penetrates the N type well layer 7 in the high-withstand-voltage isolation region 3 in the thickness direction. That is, the element structure 21 of the high-withstand-voltage isolation region 3 is dielectrically isolated by the trench 26. A buried oxide film layer 27 is provided between the P type substrate 4 and the P type well layer 6 and the N type well layer 7.

According to the semiconductor device 1060, because the field plate does not exist on the high-withstand-voltage isolation region 3, the electric field intensity in the vertical direction is weakened, but the process cost increases due to the trench isolation structure. Accordingly, the structure of the sixth preferred embodiment is preferably applied in the case where the dielectric isolation structure is required in the low potential region 1 or the high potential region 2.

Although the preferred embodiments and the like have been described in detail above, the present invention is not limited to the above-described preferred embodiments and the like, and various modifications and substitutions can be made to the above-described preferred embodiments and the like without departing from the scope described in the claims.

Hereinafter, various aspects of the present disclosure will be collectively described as appendixes.

### (Appendix 1)

A semiconductor device comprising:
a semiconductor substrate;
an element structure formed on the semiconductor substrate; and
a signal transmission element provided on the element structure in a high-withstand-voltage isolation region,
wherein in plan view, the semiconductor device is divided into:
a low potential region having a ground as a reference potential;
a high potential region having a floating potential as a reference potential; and
the high-withstand-voltage isolation region that is provided between the low potential region and the high potential region to separate the low potential region and the high potential region from each other,
the signal transmission element includes:
a primary-side element that is provided on the low potential region side of the high-withstand-voltage isolation region and connected to the low potential region; and
a secondary-side element that is provided on the high potential region side of the high-withstand-voltage isolation region and connected to the high potential region, and
the primary-side element and the secondary-side element are magnetically coupled or capacitively coupled to each other by a magnetic field or an electric field in a direction parallel to a main surface of the semiconductor substrate.

### (Appendix 2)

The semiconductor device according to Appendix 1, wherein the primary-side element is a primary coil that is a lateral coil having a coil axis in the direction parallel to a main surface of the semiconductor substrate,
the secondary-side element is a secondary coil that is a lateral coil having a coil axis in the direction parallel to a main surface of the semiconductor substrate, and
the primary coil and the secondary coil are magnetically coupled to each other by a magnetic field in the direction parallel to a main surface of the semiconductor substrate.

### (Appendix 3)

The semiconductor device according to Appendix 2, comprising an N-layer metal wiring formed on the element structure as N is a natural number at least 4,
wherein the lateral coil includes the metal wirings of a second layer and an Nth layer, and
the metal wirings of the second layer and an Nth layer configuring the one lateral coil is vertically connected by the metal wirings of a third layer to an (N−1)th layer.

### (Appendix 4)

The semiconductor device according to Appendix 2, comprising an N-layer metal wiring formed on the element structure as N is a natural number at least 4,
wherein the lateral coil includes the metal wirings of a second layer and an Nth layer, and
the metal wirings of a third layer to an (N−1)th layer are made of a magnetic material to configure a coil core of the lateral coil.

### (Appendix 5)

The semiconductor device according to Appendix 2, comprising a two-layer metal wiring formed on the element structure,
wherein the lateral coil includes the metal wirings of a first layer and a second layer.

### (Appendix 6)

The semiconductor device according to Appendix 2, comprising an N-layer metal wiring formed on the element structure as N is a natural number at least 3,
wherein the lateral coil includes the metal wirings of a first layer and an Nth layer, and
the metal wirings of a second layer and an Nth layer configuring the one lateral coil are vertically connected by the metal wirings of a second layer to an (N−1)th layer.

### (Appendix 7)

The semiconductor device according to Appendix 2, comprising an N-layer metal wiring formed on the element structure as N is a natural number at least 3,
wherein the lateral coil includes the metal wirings of a first layer and an Nth layer, and
the metal wirings of a second layer to an (N−1)th layers are made of a magnetic material to configure a coil core of the lateral coil.

### (Appendix 8)

The semiconductor device according to Appendix 2, wherein the primary coil and the secondary coil are disposed such that coil axes of the primary coil and the secondary coil are parallel to each other.

### (Appendix 9)

The semiconductor device according to Appendix 1, wherein the primary-side element is a primary plate electrode having a first surface parallel to a thickness direction of the semiconductor substrate,
the secondary-side element is a secondary plate electrode having a second surface that is parallel to a thickness direction of the semiconductor substrate and is opposite to the first surface, and
the primary plate electrode and the secondary plate electrode are capacitively coupled to each other by an electric field between the first surface and the second surface in the direction parallel to a main surface of the semiconductor substrate.

### (Appendix 10)

The semiconductor device according to Appendix 9, wherein the first surface and the second surface meander in plan view and are engaged with each other in a comb shape.

### (Appendix 11)

The semiconductor device according to Appendix 1, wherein the signal transmission element is provided on an entire surface of the high-withstand-voltage isolation region.

### (Appendix 12)

A semiconductor device comprising:
a semiconductor substrate;
an element structure formed on the semiconductor substrate; and
a signal transmission element provided on the element structure over a low potential region, a high-withstand-voltage isolation region, and a high potential region,
wherein in plan view, the semiconductor device is divided into:
the low potential region having a ground as a reference potential;
the high potential region having a floating potential as a reference potential; and
the high-withstand-voltage isolation region that is provided between the low potential region and the high potential region to separate the low potential region and the high potential region from each other,
the signal transmission element includes:
a primary coil provided in the low potential region;
a secondary coil provided in the high potential region; and
a coil core that is made of a magnetic material inserted into both the primary coil and the secondary coil across the high-withstand-voltage isolation region, and
the primary coil and the secondary coil are magnetically coupled to each other by a magnetic field in the direction parallel to a main surface of the semiconductor substrate.

### (Appendix 13)

The semiconductor device according to any one of Appendixes 4, 7, and 12, wherein the magnetic material is cobalt.

### (Appendix 14)

The semiconductor device according to any one of Appendixes 1 to 12, wherein the element structure of the high-withstand-voltage isolation region includes a resistive field plate.

### (Appendix 15)

The semiconductor device according to any one of Appendixes 1 to 12, wherein the element structure of the high-withstand-voltage isolation region includes a capacitive coupling type field plate.

### (Appendix 16)

The semiconductor device according to any one of Appendixes 1 to 12, wherein the element structure of the high-withstand-voltage isolation region is dielectrically isolated by a trench.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
an element structure formed on the semiconductor substrate; and
a signal transmission element provided on the element structure in a high-withstand-voltage isolation region,
wherein in plan view, the semiconductor device is divided into:
a low potential region having a ground as a reference potential;
a high potential region having a floating potential as a reference potential; and
the high-withstand-voltage isolation region that is provided between the low potential region and the high potential region to separate the low potential region and the high potential region from each other,
the signal transmission element includes:
a primary-side element that is provided on the low potential region side of the high-withstand-voltage isolation region and connected to the low potential region; and
a secondary-side element that is provided on the high potential region side of the high-withstand-voltage isolation region and connected to the high potential region, and
the primary-side element and the secondary-side element are magnetically coupled or capacitively coupled to each other by a magnetic field or an electric field in a direction parallel to a main surface of the semiconductor substrate.

2. The semiconductor device according to claim 1, wherein the primary-side element is a primary coil that is a lateral coil having a coil axis in the direction parallel to a main surface of the semiconductor substrate,
the secondary-side element is a secondary coil that is a lateral coil having a coil axis in the direction parallel to a main surface of the semiconductor substrate, and
the primary coil and the secondary coil are magnetically coupled to each other by a magnetic field in the direction parallel to a main surface of the semiconductor substrate.

3. The semiconductor device according to claim 2, comprising an N-layer metal wiring formed on the element structure as N is a natural number at least 4,
wherein the lateral coil includes the metal wirings of a second layer and an Nth layer, and
the metal wirings of a second layer and an Nth layer configuring the one lateral coil are vertically connected by the metal wirings of a third layer to an (N−1)th layer.

4. The semiconductor device according to claim 2, comprising an N-layer metal wiring formed on the element structure as N is a natural number at least 4,
wherein the lateral coil includes the metal wirings of a second layer and an Nth layer, and
the metal wirings of a third layer to an (N−1)th layer are made of a magnetic material to configure a coil core of the lateral coil.

5. The semiconductor device according to claim 2, comprising a two-layer metal wiring formed on the element structure, and
the lateral coil includes the metal wirings of a first layer and a second layer.

6. The semiconductor device according to claim 2, comprising an N-layer metal wiring formed on the element structure as N is a natural number at least 3,
wherein the lateral coil includes the metal wirings of a first layer and an Nth layer, and
the metal wirings of a first layer and an Nth layer configuring the one lateral coil are vertically connected by the metal wirings of a second layer to an (N−1)th layer.

7. The semiconductor device according to claim 2, comprising an N-layer metal wiring formed on the element structure as N is a natural number at least 3,
wherein the lateral coil includes the metal wirings of a first layer and an Nth layer, and
the metal wirings of a second layer to an (N−1)th layers are made of a magnetic material to configure a coil core of the lateral coil.

8. The semiconductor device according to claim 2, wherein the primary coil and the secondary coil are disposed such that coil axes of the primary coil and the secondary coil are parallel to each other.

9. The semiconductor device according to claim 1, wherein the primary-side element is a primary plate electrode having a first surface parallel to a thickness direction of the semiconductor substrate,
the secondary-side element is a secondary plate electrode having a second surface that is parallel to a thickness direction of the semiconductor substrate and is opposite to the first surface, and
the primary plate electrode and the secondary plate electrode are capacitively coupled to each other by an electric field between the first surface and the second surface in the direction parallel to a main surface of the semiconductor substrate.

10. The semiconductor device according to claim 9, wherein the first surface and the second surface meander in plan view and are engaged with each other in a comb shape.

11. The semiconductor device according to claim 1, wherein the signal transmission element is provided on an entire surface of the high-withstand-voltage isolation region.

12. A semiconductor device comprising:
a semiconductor substrate;
an element structure formed on the semiconductor substrate; and
a signal transmission element provided on the element structure over a low potential region, a high-withstand-voltage isolation region, and a high potential region,
wherein in plan view, the semiconductor device is divided into:
the low potential region having a ground as a reference potential;
the high potential region having a floating potential as a reference potential; and
the high-withstand-voltage isolation region that is provided between the low potential region and the high potential region to separate the low potential region and the high potential region from each other,
the signal transmission element includes:
a primary coil provided in the low potential region;
a secondary coil provided in the high potential region; and
a coil core that is made of a magnetic material inserted into both the primary coil and the secondary coil across the high-withstand-voltage isolation region, and
the primary coil and the secondary coil are magnetically coupled to each other by a magnetic field in the direction parallel to a main surface of the semiconductor substrate.

13. The semiconductor device according to claim 4, wherein the magnetic material is cobalt.

14. The semiconductor device according to claim 1, wherein the element structure of the high-withstand-voltage isolation region includes a resistive field plate.

15. The semiconductor device according to claim 1, wherein the element structure of the high-withstand-voltage isolation region includes a capacitive coupling type field plate.

16. The semiconductor device according to claim 1, wherein the element structure of the high-withstand-voltage isolation region is dielectrically isolated by a trench.

17. The semiconductor device according to claim 7, wherein the magnetic material is cobalt.

18. The semiconductor device according to claim 12, wherein the magnetic material is cobalt.

19. The semiconductor device according to claim 12, wherein the element structure of the high-withstand-voltage isolation region includes a resistive field plate.

20. The semiconductor device according to claim 12, wherein the element structure of the high-withstand-voltage isolation region includes a capacitive coupling type field plate.

21. The semiconductor device according to claim 12, wherein the element structure of the high-withstand-voltage isolation region is dielectrically isolated by a trench.
